(19) United States
(12) Patent Application Publication
(10) Pub. No.: US 2023/0197415 A1
(43) Pub. Date: Jun. 22, 2023

(54) PROCESS GAS SUPPLYING UNIT AND SUBSTRATE TREATING APPARATUS INCLUDING THE SAME

(71) Applicant: SEMES CO., LTD., Chungcheongnam-do (KR)

(72) Inventors: In Seong LIM, Chungcheongnam-do (KR); Loung Sue CHANG, Chungcheongnam-do (KR); Jung Yoon YANG, Chungcheongnam-do (KR); Sun Ryum LEE, Chungcheongnam-do (KR); Seung Hoon JEON, Gyeonggi-do (KR); Kyoung Rae LEE, Chungcheongnam-do (KR)

(21) Appl. No.: 17/993,996

(22) Filed: Nov. 25, 2022

(30) Foreign Application Priority Data
Dec. 17, 2021 (KR) 10-2021-0182074

(51) Int. Cl. H01J 37/32; H01L 21/683

(52) U.S. Cl. CPC H01J 37/32449; H01J 37/32568; H01J 37/32082; H01L 21/6831; H01J 2237/032; H01J 2237/335

(57) ABSTRACT

The present disclosure relates to a process gas supplying unit configured to uniformly supply a process gas to each region of a substrate when a substrate is treated using plasma, and a substrate treating apparatus including the same. According to the present disclosure, the effect of improving the treating efficiency of the substrate may be obtained by uniformly supplying the process gas.

### CROSS-REFERENCE TO RELATED APPLICATION

This application claims priority from Korean Patent Application No. 10-2021-0182074 filed on Dec. 17, 2021 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a process gas supplying unit and a substrate treating apparatus including the same. More particularly, the present disclosure relates to a process gas supplying unit and a substrate treating apparatus including the same used to manufacture a semiconductor device.

### 2. Description of the Related Art

A semiconductor device manufacturing process may be continuously performed in the semiconductor device manufacturing facility and may be divided into a pre-process and a post-process. The semiconductor device manufacturing facility may be installed in a space defined by a fab to manufacture a semiconductor device.

The pre-process is defined as a process of completing a chip by forming a circuit pattern on a wafer. The pre-process may include a deposition process of forming a thin film on a wafer, a photo lithography process of transferring a photoresist onto a thin film using a photo mask, an etching process of selectively removing unnecessary parts to form a desired circuit pattern on a wafer by using chemicals or reactive gas, an ashing process of removing photoresist remaining after etching, an ion implantation process of injecting ions into a part connected to a circuit pattern to have characteristics of an electronic device, and, finally, a cleaning process of removing a contamination source from a wafer.

The post-process is defined as a process of evaluating the performance of a completed product through the pre-process. The post-process may include a primary inspection process of selecting good and defective chips by checking whether each chip on a wafer operates, a package process of cutting and separating respective chips via dicing, die bonding, wire bonding, molding, and marking to form a product shape, and a final inspection process of finally inspecting characteristics and reliability of products via electrical characteristics inspection, burn-in inspection, and so forth.

### SUMMARY

When a desired pattern is to be formed on a substrate (for example, a wafer), a process gas may be supplied into a vacuum chamber where the substrate is disposed, and plasma may be generated by using an electrode installed in the vacuum chamber to treat the substrate. In that case, when the process gas is uniformly supplied to each region on the substrate, efficiency related to substrate treatment may be improved.

Technical aspects to be achieved through one embodiment by the present disclosure provide a process gas supplying unit for uniformly supplying a process gas to each region on a substrate, and a substrate treating apparatus including the same.

The technical aspects of the present disclosure are not restricted to those set forth herein, and other unmentioned technical aspects will be clearly understood by one of ordinary skill in the art to which the present disclosure pertains by referencing the detailed description of the present disclosure given below.

In order to achieve the technical aspects, an aspect of a substrate treating apparatus of the present disclosure comprises: a housing; a second electrode disposed inside the housing and configured to support a substrate; a first electrode disposed inside or outside the housing and configured to face the second electrode; a process gas supplying unit configured to supply a process gas inside the housing; and a plasma generation unit configured to generate plasma in the housing using a first high frequency power source connected to the first electrode and a second high frequency power source connected to the second electrode, when the process gas is supplied, and the process gas supplying unit comprises: an injection nozzle installed on an inner sidewall of the housing and configured to inject the process gas; and a rotation controller installed on an outer sidewall of the housing, connected to the injection nozzle via a hole formed to penetrate the inner sidewall of the housing and configured to rotate the injection nozzle.

The rotation controller may automatically rotate the injection nozzle along the circumference of the inner sidewall of the housing.

The rotation controller may include: a body; a process gas inlet installed in the body and configured to introduce the process gas from the outside; and a shaft coupled to the body and interlocked with a drive unit to supply a rotational force to the body.

The rotation controller may further include a sealing member configured to maintain airtightness between the body and the shaft.

The sealing member may be a magnetic seal.

The process gas inlet may be formed by using the height direction of the housing as a longitudinal direction, or may be formed by using a direction opposite to the height direction of the housing as a longitudinal direction.

The process gas supplying unit may further include a process gas supply source configured to supply the process gas; and a process gas supplying line configured to move the process gas to the injection nozzle.

The process gas supplying line may connect the process gas supply source and the rotation controller and move the process gas to the injection nozzle via the rotation controller.

The rotation controller may control a rotation speed of the injection nozzle.

A plurality of injection nozzles may be installed along the circumference of the inner sidewall of the housing, and the rotation controller may be connected to at least one injection nozzle among the plurality of injection nozzles.

The substrate treating apparatus may further include a shower head unit disposed on an upper part of the substrate in the housing and including a plurality of gas injection holes on a surface thereof, and the process gas supplying unit may be connected to the shower head unit via a hole formed to penetrate the upper part of the housing.

The process gas supplying unit may supply the process gas into the housing by using one of the injection nozzle and the shower head unit, or may supply the process gas into the housing by using one of the injection nozzle and the shower head unit and then supply the process gas into the housing by using the other thereof.

The substrate treating apparatus may be a vacuum chamber.

In addition, in order to achieve the technical aspects, the other aspect of a substrate treating apparatus of the present disclosure comprises: a housing; a second electrode disposed inside the housing and configured to support a substrate; a first electrode disposed inside or outside the housing and configured to face the second electrode; a process gas supplying unit configured to supply a process gas into the housing; and a plasma generation unit configured to generate plasma in the housing using a first high frequency power source connected to the first electrode and a second high frequency power source connected to the second electrode, when the process gas is supplied, and the process gas supplying unit comprises: an injection nozzle installed on an inner sidewall of the housing and configured to inject the process gas; and a rotation controller installed on an outer sidewall of the housing, connected to the injection nozzle via a hole formed to penetrate the inner sidewall of the housing and configured to rotate the injection nozzle. The rotation controller comprises: a body; a process gas inlet installed in the body and configured to introduce the process gas from the outside; a shaft coupled to the body and interlocked with a drive unit to supply a rotational force to the body; a sealing member configured to maintain airtightness between the body and the shaft, and the rotation controller automatically rotates the injection nozzle along the circumference of the inner sidewall of the housing, and the sealing member is a magnetic seal.

In addition, in order to achieve the technical aspects, one aspect of a process gas supplying unit of the present disclosure, which supplies a process gas to the inside of a substrate treating apparatus that is a vacuum chamber and treats a substrate using plasma, comprises: a process gas supply source configured to supply the process gas; an injection nozzle installed on an inner sidewall of the substrate treating apparatus and configured to inject the process gas into the substrate treating apparatus; a process gas supplying line configured to move the process gas to the injection nozzle; and a rotation controller installed on an outer sidewall of the housing, connected to the injection nozzle via a hole formed to penetrate the inner sidewall of the housing and configured to rotate the injection nozzle.

Details of other embodiments are included in the detailed description and drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a cross-sectional view exemplarily illustrating an internal structure of a substrate treating apparatus according to one embodiment of the present disclosure;

FIG. 2 is an exemplary view illustrating a problem in a case where a process gas is supplied to a side surface of the substrate treating apparatus;

FIG. 3 is a first exemplary view schematically illustrating an internal structure of a process gas supplying unit installed on a sidewall of the substrate treating apparatus according to one embodiment of the present disclosure;

FIG. 4 is a second exemplary view schematically illustrating the internal structure of the process gas supplying unit installed on the sidewall of the substrate treating apparatus according to one embodiment of the present disclosure;

FIG. 5 is a third exemplary view schematically illustrating the internal structure of the process gas supplying unit installed on the sidewall of the substrate treating apparatus according to one embodiment of the present disclosure;

FIG. 6 is an exemplary view schematically illustrating an arrangement structure of the process gas supplying unit installed on the sidewall of the substrate treating apparatus according to one embodiment of the present disclosure;

FIG. 7 is a first exemplary view schematically illustrating an internal structure of a substrate treating apparatus according to another embodiment of the present disclosure;

FIG. 8 is a second exemplary view schematically illustrating the internal structure of the substrate treating apparatus according to another embodiment of the present disclosure; and

FIG. 9 is a third exemplary view schematically illustrating the internal structure of the substrate treating apparatus according to another embodiment of the present disclosure.

### DETAILED DESCRIPTION OF THE EMBODIMENTS

Hereinafter, embodiments of the present disclosure will be described with reference to the attached drawings. The same reference numerals indicate the same elements throughout the specification, and redundant descriptions thereof will be omitted.

The present disclosure relates to a process gas supplying unit configured to uniformly supply a process gas to each region of a substrate when a substrate is treated using plasma, and a substrate treating apparatus including the same. According to the present disclosure, the effect of improving the treating efficiency of the substrate may be obtained by uniformly supplying the process gas. Hereinafter, the present disclosure will be described in detail with reference to the attached drawings:

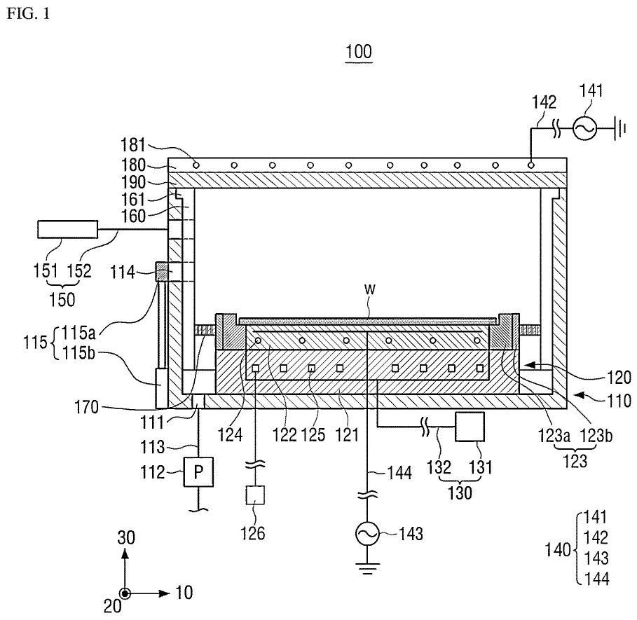

FIG. 1 is a cross-sectional view exemplarily illustrating an internal structure of a substrate treating apparatus according to one embodiment of the present disclosure.

According to FIG. 1, the substrate treating apparatus 100 may include a housing 110, a substrate support unit 120, a cleaning gas supplying unit 130, a plasma generation unit 140, a process gas supplying unit 150, a liner unit 160, a baffle unit 170 and an antenna unit 180.

The substrate treating apparatus 100 is an apparatus for treating a substrate W (for example, a wafer) using plasma. The substrate treating apparatus 100 may etch or clean the substrate W in a vacuum environment, or may deposit on the substrate W. For example, the substrate treating apparatus 100 may be implemented with an etching process chamber or a cleaning process chamber or implemented with a deposition process chamber.

The housing 110 provides a process of treating the substrate W using plasma, that is, a space in which a plasma process is executed. The housing 110 may include an exhaust hole 111 formed at a lower part thereof.

The exhaust hole 111 may be connected to an exhaust line 113 in which a pump 112 is mounted. The exhaust hole 111 may discharge by-products generated during a plasma process and gas remaining in the housing 110 to the outside of the housing 110 via the exhaust line 113. In that case, an inner space of the housing 110 may be decompressed to a predetermined pressure.

The housing 110 may have an opening 114 formed on a sidewall thereof. The opening 114 may function as a passage through which a substrate W enters and exits the inside of the housing 110. The opening 114 may be opened and closed by a door assembly 115.

The door assembly 115 may include an outer door 115a and a door driver 115b. The outer door 115a is provided on an outer sidewall of the housing 110. The outer door 115a may be moved in the height direction of the substrate treating apparatus 100 through the door driver 115b, that is, in the third direction 30. The door driver 115b may operate using at least one selected from a motor, a hydraulic cylinder, and a pneumatic cylinder.

The substrate support unit 120 is installed in an inner lower region of the housing 110. The substrate support unit 120 may support the substrate W using electrostatic force. However, the present embodiment is not limited thereto. The substrate support unit 120 can support the substrate (W) in a variety of ways such as mechanical clamping and vacuum.

When the substrate support unit 120 supports the substrate W using the electrostatic force, the substrate support unit 120 may include a base 121 and an electrostatic chuck (ESC) 122.

The electrostatic chuck 122 is a substrate support member that supports the substrate W mounted on an upper part thereof using the electrostatic force. The electrostatic chuck 122 may be formed of a ceramic material and may be coupled to the base 121 so that it is fixed on the base 121.

Although not illustrated in FIG. 1, the electrostatic chuck 122 may be installed to be movable in the third direction 30 inside the housing 110 using a drive member. When the electrostatic chuck 122 is movable in the height direction of the substrate treating apparatus 100, it is possible to dispose the substrate W in a region indicative of a more uniform plasma distribution.

A ring assembly 123 is provided to surround an edge of the electrostatic chuck 122. The ring assembly 123 may be provided in a ring shape to cover an edge region of the substrate W. The ring assembly 123 may include a focus ring 123a and an edge ring 123b.

The focus ring 123a may be formed inside the edge ring 123b and provided to directly surround the electrostatic chuck 122. The focus ring 123a may be formed of a silicon material and may serve to concentrate ions on the substrate W when a plasma process is advanced inside the housing 110.

The edge ring 123b may be formed outside the focus ring 123a and provided to surround the focus ring 123a. As the edge ring 123b is an insulator ring, the edge ring 123b may be formed of a quartz material and may serve to prevent a side surface of the electrostatic chuck 122 from being damaged by plasma.

A heating member 124 and a cooling member 125 are provided to maintain the substrate W at a process temperature when a substrate treating process is conducted inside the housing 110. The heating member 124 may be provided as a hot wire to increase the temperature of the substrate W and may be installed in the substrate support unit 120, for example, in the electrostatic chuck 122. The cooling member 125 may be provided as a cooling line through which a refrigerant flows to decrease the temperature of the substrate W and may be installed in the substrate support unit 120, for example, in the base 121.

Meanwhile, the cooling member 125 may receive the refrigerant using a cooling device 126. The cooling device 126 may be separately installed outside the housing 110.

The cleaning gas supplying unit 130 supplies a first gas to remove foreign substances remaining in the electrostatic chuck 122 or the ring assembly 123. To this end, the cleaning gas supplying unit 130 may include a cleaning gas supply source 131 and a cleaning gas supplying line 132.

The cleaning gas supply source 131 may supply nitrogen gas (N2 Gas) as a cleaning gas. The cleaning gas supply source 131 may supply other gases or other cleaning agents other than the nitrogen gas as long as it may effectively remove foreign substances remaining in the electrostatic chuck 122 or the ring assembly 123.

The cleaning gas supplying line 132 transmits the cleaning gas supplied by the cleaning gas supply source 131. The cleaning gas supplying line 132 may be connected to a space between the electrostatic chuck 122 and the focus ring 123a, and the cleaning gas may move through the space to remove the foreign materials remaining in an edge of the electrostatic chuck 122 or an upper part of the ring assembly 123.

The plasma generation unit 140 generates plasma from gas remaining in a discharge space. Herein, the discharge space refers to a space disposed above the substrate support unit 120 in an inner space of the housing 110.

The plasma generation unit 140 may generate plasma in the discharge space inside the housing 110 using an inductively coupled plasma (ICP) source. That is, the plasma generation unit 140 may generate plasma in the discharge space inside the housing 110 using the inductively coupled plasma (ICP) source. In that case, the plasma generation unit 140 may use, for example, the antenna unit 180 as a first electrode, and the electrostatic chuck 122 as a second electrode.

The plasma generation unit 140 may include a first high frequency power source 141, a first transmission line 142, the first electrode, a second high frequency power source 143, a second transmission line 144, and the second electrode.

The first high frequency power source 141 applies RF power to the first electrode. For example, when the antenna unit 180 is used as the first electrode, the first high frequency power source 141 may apply the RF power to the antenna unit 180.

The first transmission line 142 connects the first electrode and GND. The first high frequency power source 141 may be installed on the first transmission line 142.

The first high frequency power source 141 may serve to control characteristics of the plasma in the substrate treating apparatus 100. For example, the first high frequency power source 141 may serve to control ion bombardment energy.

The number of first high frequency power sources 141 may be one in the substrate treating apparatus 100, but a plurality of first high frequency power sources 141 can be provided. When a plurality of first high frequency power sources 141 are provided in the substrate treating apparatus 100, they may be disposed in parallel on the first transmission line 142.

When the plurality of first high frequency power sources 141 are provided in the substrate processing apparatus 100, although not illustrated in FIG. 1, the plasma generation unit 140 may further include a first matching network electrically connected to the plurality of first high frequency power sources. Herein, when frequency power of different sizes is input from each of the first high frequency power sources, the first matching network may match and apply the frequency power to the first electrode.

Meanwhile, although not illustrated in FIG. 1, a first impedance matching circuit may be provided on the first transmission line 142 configured to connect the first high frequency power source 141 and the first electrode for the purpose of impedance matching. The first impedance matching circuit may serve as a lossless manual circuit, thus allowing maximum electrical energy to be transmitted from the first high frequency power source 141 to the first electrode.

The second high frequency power source 143 applies RF power to the second electrode. For example, when the electrostatic chuck 122 is used as the second electrode, the second high frequency power source 143 may apply the RF power to the electrostatic chuck 122.

The second transmission line 144 connects the second electrode and the GND. The second high frequency power source 143 may be installed on the second transmission line 144.

The second high frequency power source 143 may serve as a plasma source configured to generate plasma in the substrate treating apparatus 100. In addition, the second high frequency power source 143 may serve to control plasma characteristics together with the first high frequency power source 141.

The number of second high frequency power sources 143 may be one in the substrate treating apparatus 100, but a plurality of second high frequency power sources 143 may be provided. When the plurality of second high frequency power sources 143 are provided in the substrate treating apparatus 100, they may be disposed in parallel on the second transmission line 144.

When the plurality of second high frequency power sources 143 are provided in the substrate treating apparatus 100, although not illustrated in FIG. 1, the plasma generation unit 140 may further include a second matching network electrically connected to the plurality of second high frequency power sources. Herein, when frequency power of different sizes is input from each of the second high frequency power sources, the second matching network may match and apply the frequency power to the second electrode.

Meanwhile, although not illustrated in FIG. 1, a second impedance matching circuit may be provided on the second transmission line 144 configured to connect the second high frequency power source 143 and the second electrode for the purpose of impedance matching.

The second impedance matching circuit may server as a lossless manual circuit, thus allowing maximum electrical energy to be transmitted from the second high frequency power source 143 to the second electrode.

When the second high frequency power source 143 is installed on the second transmission line 144, the plasma generation unit 140 may apply multiple frequencies to the substrate treating apparatus 100, thereby improving substrate treating efficiency of the substrate treating apparatus 100. However, the present embodiment is not limited thereto. The plasma generation unit 140 can be configured without including the second high frequency power source 143. In other words, the second high frequency power source 143 may not be installed on the second transmission line 144.

The process gas supplying unit 150 supplies the process gas to the inner space of the housing 110. The process gas supplying unit 150 may be installed on a side surface of the housing 110. The process gas supplying unit 150 will be described in more detail below.

The liner unit 160 is meant to protect the inside of the housing 110 from arc discharge generated during the process of exciting the process gas or impurities generated during the substrate treatment process. To this end, the liner unit 160 may be formed to cover an inner sidewall of the housing 110.

The liner unit 160 may include a support ring 161 formed on an upper part thereof. The support ring 161 is formed to protrude from the top of the liner unit 160 in an outward direction (i.e., a first direction 10) and may serve to fix the liner unit 160 to the housing 110.

The baffle unit 170 serves to exhaust by-products of a plasma process and unreacted gas. The baffle unit 170 may be installed between the inner sidewall of the housing 110 and the substrate support unit 120.

The baffle unit 170 may be provided in an annular ring shape and may have a plurality of through holes penetrating in a vertical direction (i.e., a third direction 30). The baffle unit 170 may control the flow of the process gas according to the number and shape of the through holes.

The antenna unit 180 serves to generate a magnetic field and an electric field in the housing 110 to excite the process gas introduced into the housing 110 via the process gas supplying unit 150 into plasma. To this end, the antenna unit 180 may include an antenna 181 provided to form a closed loop using a coil and may use the RF power supplied from the first high frequency power source 141.

The antenna unit 180 may be installed on an upper surface of the housing 110. In that case, the antenna 181 may be installed by using the width direction of the housing 110 (i.e., the first direction 10) as the longitudinal direction and may be provided to have a size corresponding to the diameter of the housing 110.

The antenna unit 180 may be formed to have a planar type. However, the present embodiment is not limited thereto. The antenna unit 180 can be formed to have a cylindrical type. In that case, the antenna unit 180 may be installed to surround an outer sidewall of the housing 110.

Meanwhile, a window module 190 may be installed between the upper surface of the housing 110 and the antenna unit 180. In that case, the upper surface of the housing 110 may be opened, and the window module 190 may be installed to cover the upper surface of the housing 110. In other words, the window module 190 may serve as an upper cover of the housing 110 that seals the inner space of the housing 110.

The window module 190 may be formed of an insulating material (e.g., alumina (Al₂O₃)) as a dielectric window. The window module 190 may include a coating film formed on a surface thereof to suppress occurrence of particles when advancing the plasma process inside the housing 110.

As described above, the process gas supplying unit 150 is installed on the side surface of the housing 110 and supplies the process gas to the inner space of the housing 110 via a hole formed to penetrate the sidewall of the housing 110. To this end, the process gas supplying unit 150 may include a process gas supply source 151 and a process gas supplying line 152.

The process gas supply source 151 may supply gas used to process the substrate W as the process gas. The process gas supply source 151 may supply, for example, an etching gas or a cleaning gas as process gas, or may supply a deposition gas as process gas.

At least one process gas supply source 151 may be provided in the substrate treating apparatus 100. When a plurality of process gas suppling sources 151 are provided in the substrate treating apparatus 100, the effect of providing a large amount of gas within a short period of time may be obtained. On the other hand, when a plurality of process gas suppling sources 151 are provided in the substrate treating apparatus 100, the plurality of process gas suppling sources 151 can supply different gases. For example, some of the process gas supply sources 151 may supply the etching gas, while others may supply the cleaning gas, and yet others may supply the deposition gas.

The process gas supplying line 152 transmits the process gas supplied by the process gas supply source 151 into the housing 110. To this end, the process gas supplying line 152 may connect the process gas supply source 151 and the hole formed to penetrate the sidewall of the housing 110.

The substrate treating apparatus 100 may treat the substrate W using the plasma generation unit 140 and the process gas supplying unit 150. In other words, when the substrate W is disposed on the substrate support unit 120 inside the housing 110, the substrate treating apparatus 100 may treat the substrate W by supplying the process gas into the housing 110 using the process gas supplying unit 150 and generating plasma inside the housing 110 using the plasma generation unit 140.

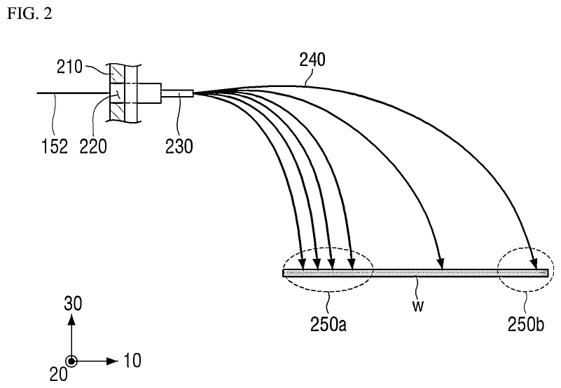

However, as illustrated in FIG. 2, when a hole 220 is formed to penetrate a sidewall 210 of the housing 110 and the injection nozzle 230 connected to the process gas supply source 151 via the hole 220 supplies a process gas 240 into the housing 110, a large amount of process gas 240 is supplied to a first region 250a of the substrate W disposed at a close distance from the injection nozzle 230, whereas a small amount of process gas 240 is supplied to a second region 250b of the substrate W disposed at a long distance from the injection nozzle 230. In other words, the process gas 240 may not be uniformly supplied to each region on the substrate W, and treating efficiency of the substrate may be reduced. FIG. 2 is an exemplary view illustrating a problem in a case where the process gas is supplied to the side surface of the substrate treating apparatus.

In the present disclosure, the injection nozzle 230 connected to the process gas supplying unit 150 rotates along the circumference of the inner sidewall of the housing 110. Accordingly, the present disclosure can uniformly supply the process gas 240 to each region on the substrate W, thereby improving treating efficiency of the substrate. Hereinafter, this will be described in detail.

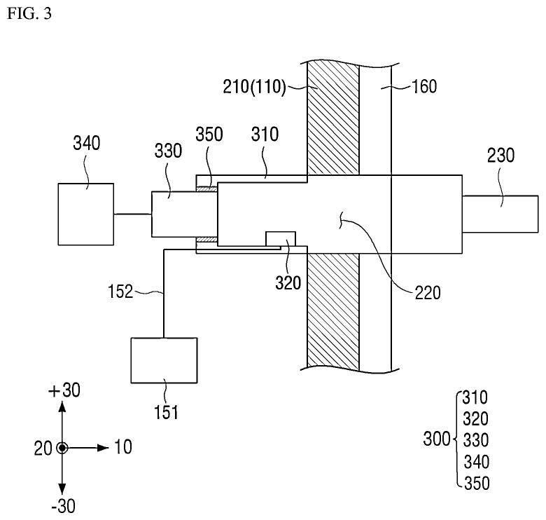

FIG. 3 is a first exemplary view schematically illustrating an internal structure of the process gas supplying unit installed on the sidewall of the substrate treating apparatus according to one embodiment of the present disclosure.

According to FIG. 3, the process gas supplying unit 150 may include the process gas supply source 151, the process gas supplying line 152, the injection nozzle 230, and a rotation controller 300.

The process gas supply source 151 and the process gas supplying line 152 have been described with reference to FIG. 1, and thus detailed descriptions thereof will be omitted.

The injection nozzle 230 supplies the process gas supplied along the process gas supplying line 152 to a region where the substrate W is disposed in the housing 110. The injection nozzle 230 may be attached to the inner sidewall of the housing 110 and may rotate along the circumference of the inner sidewall of the housing 110 (i.e., in a direction perpendicular to the height direction of the housing 110) under the control of the rotation controller 300.

The injection nozzle 230 may be installed on the inner sidewall of the housing 110 to be in a singular form. However, the present embodiment is not limited thereto. A plurality of injection nozzles 230 can be installed on the inner sidewall of the housing 110. Detailed descriptions thereof will be described below.

The rotation controller 300 rotates the injection nozzle 230 along the circumference of the inner sidewall of the housing 110. The injection nozzle 230 may uniformly supply the process gas to each region on the substrate W by means of such a role of the rotation controller 300.

The rotation controller 300 may automatically rotate the injection nozzle 230. However, the present embodiment is not limited thereto. The rotation controller 300 can manually rotate the injection nozzle 230.

When the injection nozzle 230 is automatically rotated, the rotation controller 300 may include, for example, a body 310, a process gas inlet 320, a shaft 330, a drive unit 340, and a sealing member 350.

The body 310 is meant to form a body of the rotation controller 300. The body 310 may be installed on the outer sidewall of the housing 110 and may be connected to the hole 220 formed to penetrate the sidewall of the housing 110.

The process gas inlet 320 is installed inside the body 310. The process gas may be introduced into the body 310 via the process gas inlet 320 and may be introduced into the housing 110 via the hole 220 of the sidewall of the housing 110 and the injection nozzle 230 that are connected to the body 310.

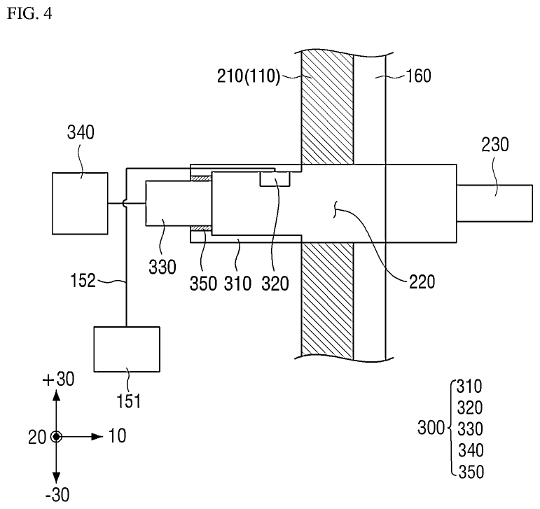

The process gas inlet 320 may be formed to extend upwards (positive third direction (+30)) from a lower surface of the body 310. However, the present embodiment is not limited thereto. The process gas inlet 320 can also be formed to extend downwards (negative third direction (−30)) from an upper surface of the body 310 as illustrated in FIG. 4. FIG. 4 is a second exemplary view schematically illustrating the internal structure of the process gas supplying unit installed on the sidewall of the substrate treating apparatus according one an embodiment of the present disclosure.

The process gas inlet 320 may be installed inside the body 310 to be in a singular form. However, the present embodiment is not limited thereto. A plurality of process gas inlets 320 can be installed inside the body 310.

When the plurality of process gas inlets 320 are installed in the body 310, all process gas inlets 320 may extend upwards from the lower surface of the body 310 or downwards from the upper surface of the body 310. However, the present embodiment is not limited thereto. Some of these process gas inlets 320 may extend upwards from the lower surface of the body 310, while other process gas inlets 320 may extend downwards from the upper surface of the body 310.

On the other hand, a part of the process gas supplying line 152 may be inserted into the body 310 and can be connected to the process gas inlet 320 through the structure formed in this way.

It will be described again with reference to FIG. 3.

The shaft 330 rotates the body 310 along the circumference of the outer sidewall of the housing 110. The body 310 may be rotated along the circumference of the outer sidewall of the housing 110 by means of such a role of the shaft 330, while the injection nozzle 230 interlocked with the body 310 may be rotated along the circumference of the inner sidewall of the housing 1100 according to the rotation of the body 310.

The shaft 330 may be inserted into a hole formed in an end of the body 310 and coupled to the body 310. The shaft 330 may supply a rotational force to the body 310 according to the operation of the drive unit 340 to rotate the body 310 along the circumference of the outer sidewall of the housing 110. For example, the shaft 330 may rotate the body 310 along the circumference of the outer sidewall of the housing 110 according to the principle of rotating a wheel using a motor.

The shaft 330 may supply the rotational force to the body 310 via a rotation transmission way using a saw-toothed wheel structure. However, the present embodiment is not limited thereto. The shaft 330 may be fixed in the body 310 and can supply the rotational force to the body 310 by supplying a pushing force or a pulling force to the body 310 according to an operation of a robot arm interlocked with the drive unit 340 (or a robot arm including the drive unit 340).

The drive unit 340 supplies power to the shaft 330. The drive unit 340 may include, for example, a step motor.

The sealing member 350 seals a gap between the shaft 330 inserted into the hole of the body 310 and the hole of the body 310. The substrate treating apparatus 100 may be provided as a vacuum chamber, and the substrate W may be treated in a vacuum state inside the housing 110. However, when the shaft 330 is inserted into the hole of the body 310 and coupled to the body 310, the gap may be formed between the shaft 330 and the body 310, which may not allow the inside of the housing 110 to ge in a vacuum state.

In order to solve this problem, the sealing member 350 may be formed between the shaft 330 and the body 310, specifically, between the shaft 330 inserted into the hole of the body 310 and the hole of the body 310. When the sealing member 350 is formed in this way, airtightness may be maintained between the shaft 330 and the body 310, and the inside of the housing 110 may be maintained in the vacuum state during the treatment of the substrate W.

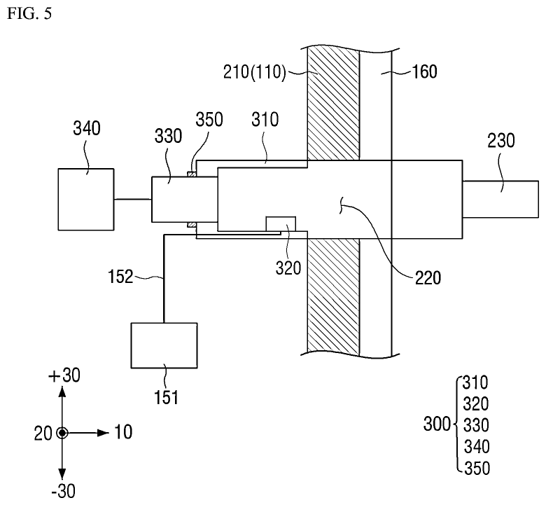

Meanwhile, the sealing member 350 may not be formed between the shaft 330 and the body 310, but can be formed on a contact part between an outer surface of the body 310 and the shaft 330 as illustrated in FIG. 5. FIG. 5 is a third exemplary view schematically illustrating the internal structure of the process gas supplying unit installed on the sidewall of a substrate treating apparatus according to one embodiment of the present disclosure.

Meanwhile, the sealing member 350 may be provided as an O-ring in the present embodiment, but may be preferably provided as a magnetic seal in order not to cause problems such as particles in the substrate treating apparatus 100.

Although not illustrated in FIGS. 3 to 5, the rotation controller 300 may further include a rotation speed control module configured to control the rotation speed of the injection nozzle 230. In that case, the rotation speed control module may be connected to the drive unit 340.

The process gas may be supplied into the housing 110 before treating the substrate W. In addition, the process gas may be supplied into the housing 110 during the treatment of the substrate W. Before treating the substrate W, the process gas may be supplied into the housing 110 at a slow speed. On the other hand, during the treatment of the substrate W, the process gas may be supplied into the housing 110 at a high speed.

Accordingly, the rotation speed control module may control the rotation speed of the injection nozzle 230 according to whether or not the substrate W is treated. In other words, the rotation speed control module may rotate the injection nozzle 230 at a slow speed before treating the substrate W and at a high speed during the treatment of the substrate W.

As described above, the plurality of injection nozzles 230 may be installed along the circumference of the inner sidewall of the housing 110. In that case, the plurality of injection nozzles 230 may be disposed at equal intervals for the purpose of uniform distribution of the process gas.

When the process gas supplying unit 150 includes the plurality of injection nozzles 230, a plurality of rotation controllers 300 may be installed on the outer sidewall of the housing 110 and coupled to the respective injection nozzles 230. However, the present embodiment is not limited thereto. The rotation controller 300 may be installed on the outer sidewall of the housing 110 to be in a singular form, and in that case, the rotation controller 300 can be coupled to one of the plurality of injection nozzles 230.

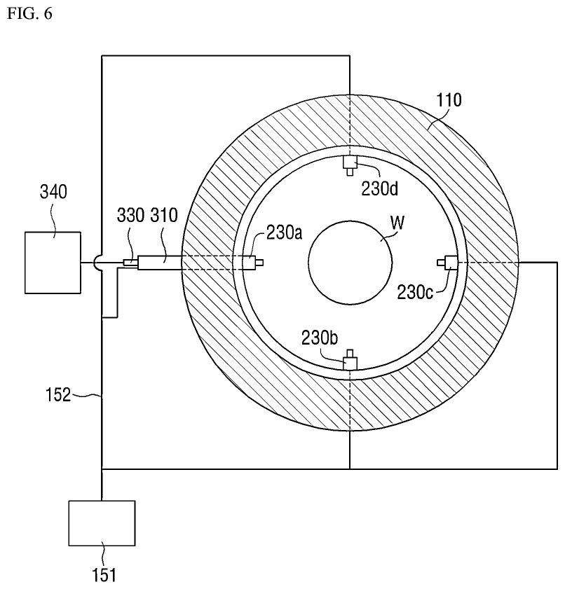

For example, as illustrated in FIG. 6, four injection nozzles 230a, 230b, 230c and 230d may be installed in the housing 110, and the rotation controller 300 may be coupled to the first injection nozzle 230a. Meanwhile, the rotation controller 300 can be coupled to all injection nozzles 230 via a connection module. FIG. 6 is an exemplary view schematically illustrating an arrangement structure of the process gas supplying unit installed on the sidewall of the substrate treating apparatus according to one embodiment of the present disclosure.

Meanwhile, when the plurality of injection nozzles 230 are installed in the housing 110, the process gas supplying unit 150 may include a process gas distributor on the process gas supplying line 152 so as to supply an equal amount of process gas to the respective injection nozzles 230, and the respective injection nozzles 230 may be connected to the process gas supplying line 152 branched by the process gas distributor.

Meanwhile, the substrate treating apparatus 100 may further include a shower head unit. Hereinafter, this case will be described.

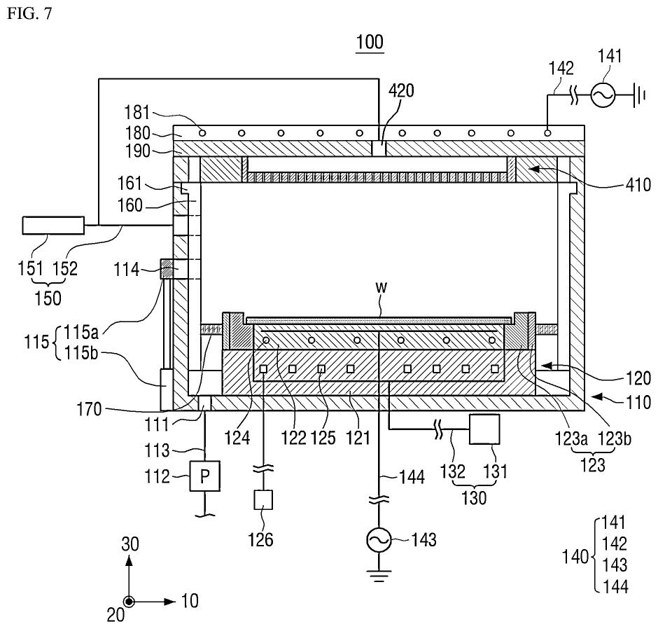

FIG. 7 is a first exemplary view schematically illustrating the internal structure of the substrate treating apparatus according to another embodiment of the present disclosure.

Referring to FIG. 7, the substrate treating apparatus 100 may include the housing 110, the substrate support unit 120, the cleaning gas supplying unit 130, the plasma generation unit 140, the process gas supplying unit 150, the liner unit 160, the baffle unit 170, the antenna unit 180, the window module 190, and the shower head unit 410.

The housing 110, the substrate support unit 120, the cleaning gas supplying unit 130, the plasma generation unit 140, the process gas supplying unit 150, the liner unit 160, the baffle unit 170, the antenna unit 180, and the window module 190 have been described above with reference to FIG. 1, and the detailed descriptions thereof will be omitted.

The shower head unit 410 includes a plurality of gas injection holes and may be installed inside the housing 110. The shower head unit 410 may be installed to face the electrostatic chuck 122 in the vertical direction (third direction 30). The shower head unit 410 may be provided to have a larger diameter than the electrostatic chuck 122 or may be provided to have the same diameter as the electrostatic chuck 122. The shower head unit 410 may be formed of a silicon material or a metal material.

The shower head unit 410 may be divided into a plurality of modules. For example, the shower head unit 410 may be divided into three modules such as a first module, a second module, and a third module. The first module may be disposed at a position corresponding to a center zone of the substrate W. The second module may be disposed to surround an outer side of the first module and may be disposed at a position corresponding to a middle zone of the substrate W. The third module may be disposed to surround an outer side of the second module and may be disposed at a position corresponding to an edge zone of the substrate W.

Meanwhile, the plurality of gas injection holes are formed to penetrate a surface of the body constituting the shower head unit 410 and may be formed at equal intervals on the body.

When the substrate treating apparatus 100 includes the shower head unit 410, the process gas supplying unit 150 may supply the process gas to the inner space of the housing 110 via the hole 220 formed to penetrate the sidewall of the housing 110, as well as supply the process gas to the inner space of the housing 110 even via a hole 420 formed to penetrate the window module 190 installed in an upper part of the housing 110. Hereinafter, the hole 220 formed to penetrate the sidewall of the housing 110 is defined as a first hole 220 and the hole 420 formed to penetrate the window module 190 is defined as a second hole 420.

When the process gas is introduced into the inner space of the housing 110 via the second hole 420, the process gas may be uniformly supplied to each region of the substrate W via the plurality of gas injection holes formed in the shower head unit 410. Accordingly, when the substrate treating apparatus 100 includes the shower head unit 410, the process gas supplying unit 150 may operate as follows.

First, the process gas supplying unit 150 may supply the process gas to the inner space of the housing 110 via the first hole 220 and the second hole 420. In that case, the process gas supplying unit 150 may simultaneously supply the process gas via both the first hole 220 and the second hole 420, as well as supply the process gas by sequentially using the first hole 220 and the second hole 420.

Second, the process gas supplying unit 150 may supply the process gas to the inner space of the housing 110 by using one of the first hole 220 and the second hole 420. For example, when the rotation controller 300 does not normally operate, the process gas supplying unit 150 may supply the process gas to the inner space of the housing 110 using the second hole 420.

Third, the process gas supplying unit 150 may supply the process gas to the inner space of the housing 110 by using one of the first hole 220 and the second hole 420 and then supply the process gas to the inner space of the housing 110 by using the other hole. For example, before treating the substrate W, the process gas supplying unit 150 may supply the process gas to the inner space of the housing 110 using the first hole 220, and during the treatment of the substrate W, the process gas supplying unit 150 may supply the process gas to the inner space of the housing 110 using the second hole 420.

Meanwhile, the substrate treating apparatus 100 described above is an example in which the plasma generating unit 140 generates plasma in the discharge space inside the housing 110 using the inductively coupled plasma source (i.e., the ICP source). However, the present embodiment is not limited thereto. The plasma generation unit 140 constituting the substrate treating apparatus 100 can generate plasma in the discharge space inside the housing 110 by using a capacitively coupled plasma (CCP) source. In other words, the plasma generation unit 140 can generate plasma in the discharge space inside the housing 110 by using the CCP source.

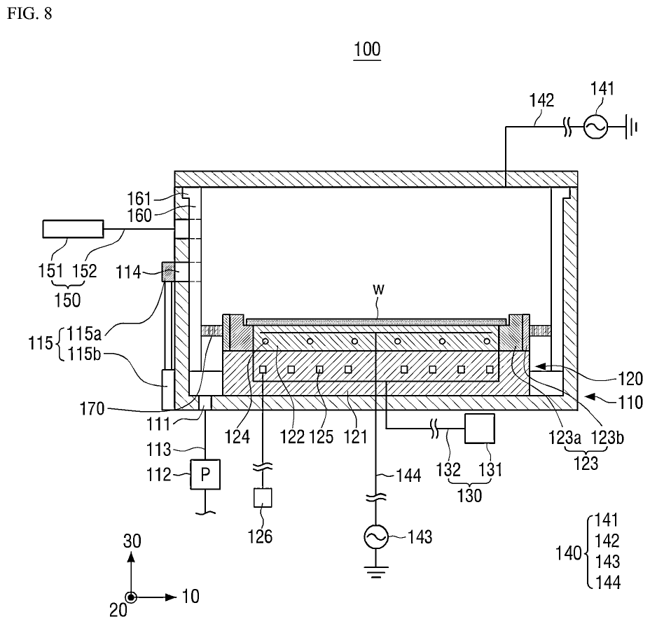

FIG. 8 is a second exemplary diagram schematically illustrating the internal structure of the substrate treating apparatus according to another embodiment of the present disclosure.

Referring to FIG. 8, the substrate treating apparatus 100 may include the housing 110, the substrate support unit 120, the cleaning gas supplying unit 130, the plasma generation unit 140, the process gas supplying unit 150, the liner unit 160, and the baffle unit 170. With respect to the substrate treating apparatus 100 in FIG. 8, only parts with differences compared with the substrate treating apparatus 100 of FIG. 1 will be described.

The plasma generation unit 140 may generate plasma in the discharge space inside the housing 110 using the CCP source. In that case, the plasma generation unit 140 may use a metal member (e.g., a member made of ceramic) installed to face the electrostatic chuck 122 above the inner/outer upper part of the housing 110 as the first electrode, and the electrostatic chuck 122 may be used as the second electrode.

Meanwhile, the process gas supplying unit 150 described with reference to FIGS. 3 to 6, i.e., the process gas supplying unit 150 installed on the sidewall of the housing 110 and including the rotation controller 300, may be equally applied to a CCP type substrate treating apparatus 100 described with reference to FIG. 8, similarly to the case of the ICP type substrate treating apparatus 100 described with reference to FIG. 1.

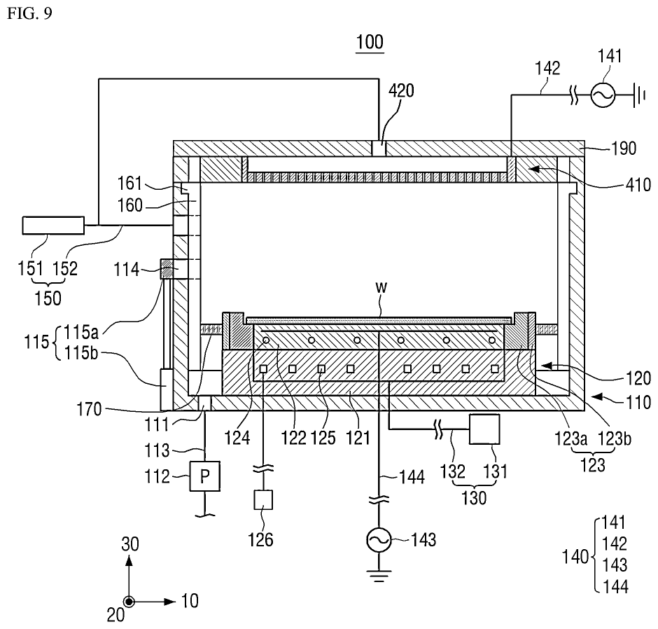

Meanwhile, the CCP type substrate treating apparatus 100 may further include the shower head unit 410 as illustrated in FIG. 9, and in that case, the process gas supplying unit 150 may be applied in the same manner as described with reference to FIG. 7. FIG. 9 is a third exemplary view schematically illustrating the internal structure of the substrate treating apparatus according to another embodiment of the present disclosure.

As described above, the substrate treating apparatus 100 including the process gas supplying unit 150 according to a variety of embodiments of the present disclosure has been described with reference to FIGS. 1 to 9. The substrate treating apparatus 100 according to the present disclosure includes a rotary gas distribution ring for uniform gas injection into a vacuum chamber. The substrate treating apparatus 100 may improve the process efficiency via the rotation of the gas distribution ring while maintaining the chamber in vacuum and high temperature conditions.

The substrate treating apparatus 100 may uniformly form the process gas in a vacuum chamber. In that case, the substrate treating apparatus 100 may form a uniform gas density inside the chamber while maintaining a vacuum via the rotation of a gas injection device (gas ring) using a magnetic seal. Accordingly, the substrate treating apparatus 100 may improve the plasma uniformity and process efficiency. Meanwhile, the gas injection device can automatically rotate to a desired position using a step motor and transmit the rotational force via saw-toothed wheel processing of the shaft.

Although the embodiments of the present disclosure have been described above with reference to the accompanying drawings, the present disclosure is not limited to the disclosed embodiments, but may be implemented in various different ways, and the present disclosure may be embodied in many different forms without changing technical subject matters and essential features as will be understood by those skilled in the art. Therefore, embodiments set forth herein are exemplary only and not to be construed as a limitation.

What is claimed is:

1. A substrate treating apparatus, comprising:
a housing;
a second electrode disposed inside the housing and configured to support a substrate;
a first electrode disposed inside or outside the housing and configured to face the second electrode;
a process gas supplying unit configured to supply a process gas into the housing; and
a plasma generation unit configured to generate plasma in the housing using a first high frequency power source connected to the first electrode and a second high frequency power source connected to the second electrode, when the process gas is supplied,
wherein the process gas supplying unit comprises:
an injection nozzle installed on an inner sidewall of the housing and configured to inject the process gas; and
a rotation controller installed on an outer sidewall of the housing, connected to the injection nozzle via a hole formed to penetrate the inner sidewall of the housing and configured to rotate the injection nozzle.

2. The substrate treating apparatus of claim 1, wherein the rotation controller automatically rotates the injection nozzle along the circumference of the inner sidewall of the housing.

3. The substrate treating apparatus of claim 1, wherein the rotation controller comprises:
a body;
a process gas inlet installed in the body and configured to introduce the process gas from the outside; and
a shaft coupled to the body and interlocked with a drive unit to supply a rotational force to the body.

4. The substrate treating apparatus of claim 3, wherein the rotation controller further comprises a sealing member configured to maintain airtightness between the body and the shaft.

5. The substrate treating apparatus of claim 4, wherein the sealing member is a magnetic seal.

6. The substrate treating apparatus of claim 3, wherein the process gas inlet is formed by using the height direction of the housing as a longitudinal direction or formed by using a direction opposite to the height direction of the housing as a longitudinal direction.

7. The substrate treating apparatus of claim 1, wherein the process gas supplying unit further comprises:
a process gas supply source configured to supply the process gas; and
a process gas supplying line configured to move the process gas to the injection nozzle.

8. The substrate treating apparatus of claim 7, wherein the process gas supplying line connects the process gas supply source and the rotation controller and moves the process gas to the injection nozzle via the rotation controller.

9. The substrate treating apparatus of claim 1, wherein the rotation controller controls a rotation speed of the injection nozzle.

10. The substrate treating apparatus of claim 1, wherein a plurality of injection nozzles are installed along the circumference of the inner sidewall of the housing, and the rotation controller is connected to at least one injection nozzle among the plurality of injection nozzles.

11. The substrate treating apparatus of claim 1, further comprising a shower head unit disposed on an upper part of the substrate in the housing and including a plurality of gas injection holes on a surface thereof,
wherein the process gas supplying unit is connected to the shower head unit via a hole formed to penetrate the upper part of the housing.

12. The substrate treating apparatus of claim 11, wherein the process gas supplying unit supplies the process gas into the housing by using one of the injection nozzle and the shower head unit, or supplies the process gas into the housing by using one of the injection nozzle and the shower head unit and then supplies the process gas into the housing by using the other thereof.

13. The substrate treating apparatus of claim 1, wherein the substrate treating apparatus is a vacuum chamber.

14. A substrate treating apparatus, comprising:
a housing;
a second electrode disposed inside the housing and configured to support the substrate;
a first electrode disposed inside or outside the housing and configured to face the second electrode;
a process gas supplying unit configured to supply a process gas into the housing; and
a plasma generation unit configured to generate plasma in the housing using a first high frequency power source connected to the first electrode and a second high frequency power source connected to the second electrode, when the process gas is supplied.
wherein the process gas supplying unit comprises:
an injection nozzle installed on an inner sidewall of the housing and configured to inject the process gas; and
a rotation controller installed on an outer sidewall of the housing, connected to the injection nozzle via a hole formed to penetrate the inner sidewall of the housing and configured to rotate the injection nozzle.
wherein the rotation controller comprises:
a body;
a process gas inlet installed in the body and configured to introduce the process gas from the outside;
a shaft coupled to the body and interlocked with a drive unit to supply a rotational force to the body;
a sealing member configured to maintain airtightness between the body and the shaft,
wherein the rotation controller automatically rotates the injection nozzle along the circumference of the inner sidewall of the housing, and the sealing member is a magnetic seal.

15. A process gas supplying unit which supplies a process gas into a substrate treating apparatus that is a vacuum chamber and treats a substrate using plasma, comprising:
a process gas supply source configured to supply the process gas;
an injection nozzle installed on an inner sidewall of the substrate treating apparatus and configured to inject the process gas into the substrate treating apparatus;
a process gas supplying line configured to move the process gas to the injection nozzle; and
a rotation controller installed on an outer sidewall of the housing, connected to the injection nozzle via a hole formed to penetrate the inner sidewall of the housing and configured to rotate the injection nozzle.

16. The process gas supplying unit of claim 15, wherein the rotation controller automatically rotates the injection nozzle along the circumference of the inner sidewall of the housing.

17. The process gas supplying unit of claim 15, wherein the rotation controller comprises:
a body;
a process gas inlet installed in the body and configured to introduce the process gas from the outside; and
a shaft coupled to the body and interlocked with a drive unit to supply a rotational force to the body.

18. The process gas supplying unit of claim 17, wherein the rotation controller further comprises a sealing member configured to maintain airtightness between the body and the shaft.

19. The process gas supplying unit of claim 18, wherein the sealing member is a magnetic seal.

20. The process gas supplying unit of claim 15, wherein the process gas supplying line connects the process gas supply source and the rotation controller and moves the process gas to the injection nozzle via the rotation controller.
